(19) United States
(12) Patent Application Publication
(10) Pub. No.: US 2024/0300819 A1
(43) Pub. Date: Sep. 12, 2024

(54) GRAPHITE SHEET AND METHOD FOR MANUFACTURING THE SAME

(71) Applicant: Panasonic Intellectual Property Management Co., Ltd., Osaka (JP)

(72) Inventors: Youji SHIRATO, Hokkaido (JP); Norihiro KAWAMURA, Hokkaido (JP); Yuji YAMAGISHI, Hokkaido (JP); Mitsuru TAMAOKI, Hokkaido (JP)

(21) Appl. No.: 18/552,398

(22) PCT Filed: Nov. 30, 2021
(86) PCT No.: PCT/JP2021/043893

§ 371 Date: Sep. 25, 2023

(30) Foreign Application Priority Data
Mar. 30, 2021 (JP) 2021-056463

(51) Int. Cl. C01B 32/21; H01L 23/00; H01L 23/42; H05K 7/20

(52) U.S. Cl. CPC C01B 32/21; H05K 7/2039; C01P 2004/03; C01P 2006/90; H01L 23/42; H01L 24/29; H01L 24/32; H01L 2224/29193; H01L 2224/32245

(57) ABSTRACT

The problem to be overcome by the present disclosure is to provide a graphite sheet with the ability to lower the contact thermal resistance at the surface of the graphite sheet. In a graphite sheet, a plurality of graphite layers are stacked one on top of another in a thickness direction. The plurality of graphite layers includes: a first graphite layer that forms an outermost layer of the graphite sheet; and a second graphite layer other than the first graphite layer. At least a part of the second graphite layer is exposed through a surface of the first graphite layer. The graphite sheet has an apparent shear strength equal to or greater than 0.1 MPa and equal to or less than 0.5 MPa as measured by SAICAS method from a depth of 0.5 m to a depth of 19 m.

### TECHNICAL FIELD

The present disclosure generally relates to a graphite sheet and a method for manufacturing the graphite sheet, and more particularly relates to a graphite sheet to be sandwiched between a heat generating part and a cooling member and a method for manufacturing such a graphite sheet.

### BACKGROUND ART

Recently, electric vehicles and hybrid vehicles, which use an electric motor as their main or auxiliary drive source (i.e., as a traction motor), have been put on the market in increasing numbers. An insulated gate bipolar transistor (IGBT) is used as an inverter to control their electric motor and is attached with screws, for example, to a cooling member to dissipate the heat generated.

Patent Literature 1 is one of the documents that teach such a heat dissipation technique. Patent Literature 1 discloses a power module with a heat dissipating part. The power module includes a base plate, a ceramic insulating substrate bonded to the base plate, and a semiconductor element bonded onto the ceramic insulating substrate. The heat dissipating part is attached to the power module to face the base plate via a heat dissipating sheet. Patent Literature 1 teaches setting the degree of planarity of the surface, opposite from the ceramic insulating substrate, of the base plate at 20 μm or less.

According to another technique, a grease, for example, is used to transfer heat smoothly from the IGBT to the cooling member. When a grease is used, however, the thermal conductivity is not sufficiently high. In addition, as the IGBT repeats the cycle of heat generation and cooling, the IGBT expands to gradually put the grease out of the IGBT, thus possibly causing deterioration in the thermal conductivity. According to still another technique, heat is transferred with a solid thermal conductive sheet such as a graphite sheet sandwiched. If such a graphite sheet is fastened with screws, however, contact thermal resistance with respect to the IGBT and the cooling member increases on the surface of the graphite sheet, thus preventing heat from being transferred sufficiently.

The graphite sheet used for such purposes may be obtained by, for example, turning a polymer film into graphite through pyrolysis. When turned into graphite, the polymer film is fired at as high a temperature as 2600° C., for example. At that time, the degree of crystallization advances more significantly in the vicinity of the surface of the graphite sheet to increase the hardness of the surface. Consequently, a part of the graphite sheet to come into contact with either the IGBT or the cooling member is too hard to make sufficient contact, thus causing an increase in contact thermal resistance.

### CITATION LIST

### Patent Literature

Patent Literature 1: JP 2019-067801 A

### SUMMARY OF INVENTION

It is therefore an object of the present disclosure to provide a graphite sheet with the ability to lower the contact thermal resistance of the surface to the point of achieving sufficient heat dissipation effects and a method for manufacturing such a graphite sheet.

In a graphite sheet according to an aspect of the present disclosure, a plurality of graphite layers are stacked one on top of another in a thickness direction. The plurality of graphite layers includes: a first graphite layer that forms an outermost layer of the graphite sheet; and a second graphite layer other than the first graphite layer. At least a part of the second graphite layer is exposed through a surface of the first graphite layer.

A graphite sheet according to another aspect of the present disclosure has an apparent shear strength equal to or greater than 0.1 MPa and equal to or less than 0.5 MPa as measured by SAICAS method from a depth of 0.5 μm to a depth of 19 μm.

A method for manufacturing a graphite sheet according to still another aspect of the present disclosure includes: a first step of obtaining a graphite base member; and a second step of forming the graphite sheet by removing a surface portion of the graphite base member obtained in the first step.

### BRIEF DESCRIPTION OF DRAWINGS

FIG. 1 is a scanning electron micrograph of a surface of a graphite sheet according to an exemplary embodiment;

FIG. 2 is a scanning electron micrograph of the surface of the graphite sheet before a surface portion thereof is removed; and

FIG. 3 is a schematic representation illustrating how to measure an apparent shear strength of the graphite sheet according to the exemplary embodiment.

### DESCRIPTION OF EMBODIMENTS

### (1) Overview

A graphite sheet and method for manufacturing the graphite sheet according to an exemplary embodiment of the present disclosure will now be described. Note that an embodiment to be described below is only an example of the present disclosure and should not be construed as limiting. Rather, the embodiment may be readily modified in various manners depending on a design choice or any other factor without departing from the scope of the present disclosure.

In general, a graphite sheet may be sandwiched between an IGBT and a cooling member and fastened with screws, for example, thereby causing the graphite sheet to make close contact with the IGBT and the cooling member while compressing the graphite sheet. In this manner, the graphite sheet may be used to smoothly transfer the heat generated by the IGBT to the cooling member. Normally, the graphite sheet is formed by conducting firing at a high temperature. At that time, the degree of crystallization advances more significantly in the vicinity of the surface of the graphite sheet to increase the hardness of the surface. Consequently, a part of the graphite sheet to come into contact with either the IGBT or the cooling member is too hard to make sufficient contact, thus causing an increase in contact thermal resistance.

To overcome this problem, the present inventors discovered that a graphite sheet manufactured by turning the surface of a graphite base member, formed by firing at a high temperature, into a particular structure by, for example, removing a surface portion of the graphite base member could have a lowered contact thermal resistance at the surface and achieve sufficient heat dissipation effects, thus conceiving the concept of the present disclosure.

Specifically, a graphite sheet according to an exemplary embodiment has either of the following two structures (1) and (2):
(1) A graphite sheet formed by stacking a plurality of graphite layers on top of another in a thickness direction, wherein the plurality of graphite layers includes: a first graphite layer that forms an outermost layer of the graphite sheet; and a second graphite layer other than the first graphite layer, and at least a part of the second graphite layer is exposed through a surface of the first graphite layer; or
(2) A graphite sheet having an apparent shear strength equal to or greater than 0.1 MPa and equal to or less than 0.5 MPa as measured by SAICAS method from a depth of 0.5 μm to a depth of 19 μm.

The graphite sheet having the structure (1) is allowed, by removing a surface portion of the graphite base member to the point that such a structure appears, for example, to have a surface soft enough to lower the contact thermal resistance at the surface and thereby achieve sufficient heat dissipation effects. On the other hand, the graphite sheet having the structure (2) is allowed, by removing a surface portion of the graphite base member to the point that the surface comes to have such an apparent shear strength, for example, to have a surface soft enough to lower the contact thermal resistance at the surface and thereby achieve sufficient heat dissipation effects.

A method for manufacturing a graphite sheet according to this embodiment includes: a first step of obtaining a graphite base member; and a second step of forming the graphite sheet by removing a surface portion of the graphite base member obtained in the first step.

The method for manufacturing a graphite sheet according to this embodiment allows a graphite sheet to be obtained by a simple method.

### (2) Details

### <Graphite Sheet>

A graphite sheet 11 according to this embodiment includes a plurality of graphite layers which are stacked one on top of another in the thickness direction. As used herein, the “graphite layer” refers to a layer of graphite that forms a single cleaved surface and includes a single or a plurality of graphene layers (preferably one to three graphene layers). The “graphene layer” as used herein refers to a layer in which carbon atoms are arranged to form a hexagonal honeycomb grid and is usually a single layer.

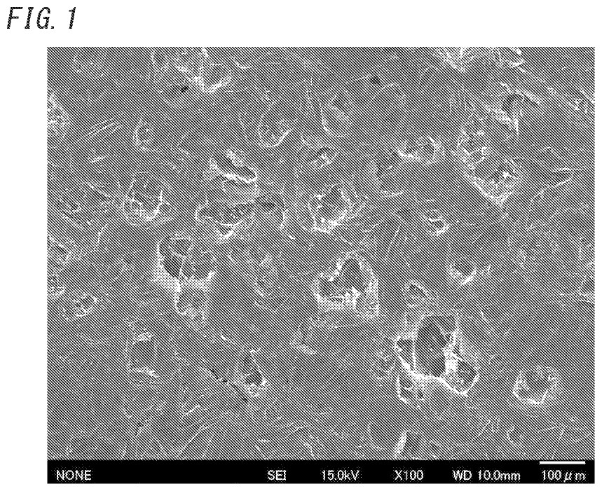

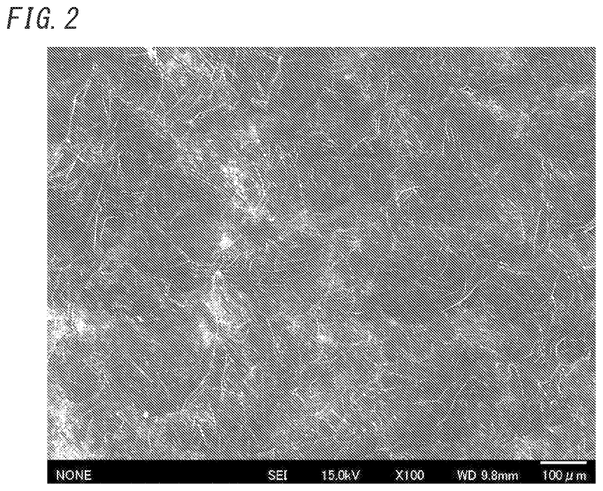

FIG. 1 is a scanning electron microscope (SEM) photograph of the surface of the graphite sheet 11 according to this embodiment. As can been from FIG. 1, through the surface of one graphite layer, which forms the outermost layer of the graphite sheet 11, at least a part of another graphite layer, other than the graphite layer forming the outermost layer, is exposed. As can be seen from the SEM photograph shown in FIG. 1, parts of the outermost graphite layer of the graphite sheet 11 have air gaps, through which the surface of another graphite layer underlying the outermost graphite layer is seen. In addition, edge portions of the graphite layer underlying the outermost graphite layer are also seen. FIG. 2 is an SEM photograph of the surface of a graphite sheet, which is different from the one according to this embodiment and taken before the surface portion thereof is removed. In the graphite sheet shown in FIG. 2, such a structure in which the non-outermost graphite layer is exposed through the outermost graphite layer is not recognized.

As can be seen from the SEM photograph shown in FIG. 1, in the graphite sheet 11, those exposed parts may form, for example, a plurality of recesses. The graphite sheet 11, having the plurality of recesses on the surface, may make closer contact with the IGBT, the cooling member, and other members. This allows the graphite sheet 11 to further lower the contact thermal resistance at the surface and further improve the heat dissipation effects. Furthermore, those recesses on the surface allows a composite structure to be formed with a resin member or any other suitable member by, for example, impregnation. The plurality of recesses preferably has an average depth equal to or greater than 3 μm and equal to or less than 30 μm. Making the average depth of the recesses equal to or greater than 3 μm improves the follow-up capability of the surface of the graphite sheet 11 so much as to decrease the thermal resistance. In addition, it also makes it even easier to form a composite structure with a resin member or any other suitable member by, for example, impregnation. In addition, making the average depth of the recesses equal to or less than 30 μm prevents the thermal resistance from increasing because the air gap is not too wide. This ensures sufficient strength for the graphite sheet 11 as well. Consequently, making the average depth of the recesses fall within this range allows the graphite sheet 11 to have a further decreased contact thermal resistance, thus further improving the heat dissipation effects as well. The average depth of the recesses is more preferably equal to or greater than 5 μm and equal to or less than 25 μm and is even more preferably equal to or greater than 7 μm and equal to or less than 20 μm. As used herein, the “average depth of the recesses” refers to an arithmetic mean calculated at ten arbitrary points with respect to the respective depths of the recesses obtained from photographs such as scanning electron micrographs.

The recesses preferably have a mean equivalent diameter equal to or greater than 30 μm and equal to or less than 100 μm. Making the mean equivalent diameter of the recesses fall within this range allows the graphite sheet 11 to make even closer surface contact, thus enabling further lowering the contact thermal resistance at the surface and further improving the heat dissipation effects. The mean equivalent diameter of the recesses is more preferably equal to or greater than 35 μm and equal to or less than 80 μm and is even more preferably equal to or greater than 40 μm and equal to or less than 60 μm. As used herein, the “mean equivalent diameter of the recesses” refers to an arithmetic mean of the diameters of circles calculated at ten arbitrary points, for example, on the supposition that the planar shape of the opening of each of the recesses is a circle having the same projection area as the opening.

The average number of the recesses per unit area is preferably equal to or greater than 5 per mm² and equal to or less than 30 per mm². Making the average number of the recesses fall within this range allows the graphite sheet 11 to make even closer surface contact, thus enabling further lowering the contact thermal resistance at the surface and further improving the heat dissipation effects. The average number of the recesses per unit area is more preferably equal to or greater than 5 per mm² and equal to or less than 25 per mm² and is even more preferably equal to or greater than 10 per mm² and equal to or less than 20 per mm². As used herein, the “average number of recesses” may be obtained from, for example, an SEM photograph representing a certain range of the surface of the graphite sheet 11.

Also, a graphite sheet 11 according to this embodiment has an apparent shear strength equal to or greater than 0.1 MPa and equal to or less than 0.5 MPa as measured by SAICAS method from a depth of 0.5 μm to a depth of 19 μm. The graphite sheet 11 according to this embodiment may have a sufficiently soft surface because the apparent shear strength as measured from a depth of 0.5 μm to a depth of 19 μm falls within this range. This allows a part of the graphite sheet 11 where the graphite sheet 11 is in contact with either the IGBT or the cooling member to be easily deformed under pressure to make close contact with either the IGBT or the cooling member. Consequently, the contact thermal resistance may be lowered at the surface, and therefore, sufficient heat dissipation effects are achieved. If this apparent shear strength were greater than 0.5 MPa, the contact thermal resistance could not be lowered sufficiently. On the other hand, if the apparent shear strength were less than 0.1 MPa, then the surface would be easily scratchable and difficult to handle. The apparent shear strength is preferably equal to or greater than 0.2 MPa and equal to or less than 0.5 MPa and is more preferably equal to or greater than 0.3 MPa and equal to or less than 0.5 MPa.

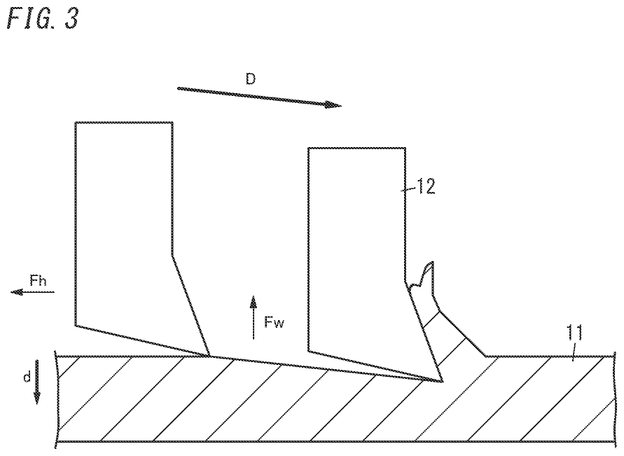

As used herein, the SAICAS method is an evaluation method called “surface and interfacial cutting analysis systems” method including cutting off a material from a surface portion thereof at low speeds using a blade with a sharp edge. FIG. 3 is a schematic representation illustrating how to measure an apparent shear strength of the graphite sheet according to the exemplary embodiment. In FIG. 3, the arrow D means that the graphite sheet is cut off obliquely and the arrow d means displacement. Using the SAICAS method allows the horizontal force (Fh) and vertical force (Fw), applied to the cutting blade when a surface portion of the graphite sheet 11 is cut off, to be measured and also allows the apparent shear strength of the surface portion to be calculated based on the horizontal force (Fh) applied to the cutting blade 12, the incisal angle of the cutting blade 12, and the cross-sectional area of the cutting blade 12. Specifically, the graphite sheet 11 is fixed onto SAICAS DN-20 (manufactured by DAIPLA WINTES Co., Ltd.), a blade having a width of 2 mm, a rake angle of 20 degrees, and a clearance angle of 10 degrees and made of boron nitride is used, and the cutting rate is set at 0.5 μm/s horizontally and 0.05 μm/s vertically in a constant velocity mode. A point where the horizontal load becomes equal to or greater than 0.002 N is supposed to be a point where the cutting blade 12 makes contact with the graphite sheet 11. From that point, measurement is made vertically to a depth of 19 μm, thereby calculating an apparent shear strength from a depth of 0.5 μm to a depth of 19 μm. The apparent shear strength is calculated by the following equation:

$$t = Fh \times ( 2 A \times Cot ( φ ) )$$

where t is the apparent shear strength, Fh is the horizontal force, A is the cross-sectional area of the cutting blade, and p is the shear angle.

If the measurement needs to be made to an even deeper region, the measurement is further continued to calculate the apparent shear strength based on the tilts between the respective depths.

In addition, 0.5≤F1/F2<1 is preferably satisfied, where F1 is an apparent shear strength as measured from a depth of 0.5 μm to a depth of 19 μm and F2 is an apparent shear strength as measured from a depth of 20 μm to a depth of a when the graphite sheet has a thickness of 2a. That is to say, it is preferable that F1 be less than F2. The allows the graphite sheet 11 to have a more sufficiently soft surface portion, thus improving the follow-up capability of the recesses and thereby further lowering the contact thermal resistance. If F1 were equal to or greater than F2, the surface portion would be so hard as to cause a decrease in the follow-up capability of the recesses and cause an increase in the contact thermal resistance. Furthermore, F1/F2≥0.5 is preferably satisfied. This makes the surface portion hardly scratchable and improves the handleability of the graphite sheet 11. On the other hand, if F1/F2 were less than 0.5, then the surface portion would be easily scratchable and the graphite sheet 11 would be difficult to handle.

An exemplary graphite sheet 11 according to this embodiment may have a thickness of about 200 μm and a compressibility of about 70% when a pressure of 600 kPa is applied thereto. The apparent shear strength of the graphite sheet 11 as measured by the SAICAS method from a depth of 0.5 μm to a depth of 19 μm may be 0.4 MPa, for example. On the other hand, the apparent shear strength of the graphite sheet 11 as measured by the SAICAS method from a depth of 20 μm to a depth of 100 μm may be 0.5 MPa, for example.

The graphite sheet 11 may have an average thickness equal to or greater than 50 μm and equal to or less than 2000 μm, for example, preferably has an average thickness equal to or greater than 100 μm and equal to or less than 1000 μm, and more preferably has an average thickness equal to or greater than 200 μm and equal to or less than 800 μm.

Also, the graphite sheet 11 preferably has a compressibility equal to or greater than 60% when a pressure of 600 kPa is applied thereto. This allows the contact thermal resistance to be lowered sufficiently. As used herein, the “compressibility” refers to the percentage notation of (T0−T1)/T0, where T0 is the initial thickness and T1 is the thickness when the pressure of 600 kPa that has been applied is removed.

The contact thermal resistance is affected by only a region around the surface of the graphite sheet 11. That is to say, the inner regions hardly contribute to the contact thermal resistance. A small apparent shear strength indicates that the sheet is in a soft condition. This means that the density is low, and the thermal conductivity is also low. That is why the inner regions preferably have a greater apparent shear strength than the surface region.

In this embodiment, the apparent shear strength as measured from a depth of 20 μm to a depth of a when the graphite sheet 11 has a thickness of 2a may be, for example, 0.5 MPa, which is greater than the apparent shear strength measured from the depth of 0.5 μm to the depth of 19 μm. This enables not only lowering the contact thermal resistance but also increasing the thermal conductivity when the graphite sheet 11 is sandwiched between the IGBT and the cooling member and fastened with screws, for example.

The graphite sheet 11 usually has two surfaces, namely, a principal surface and a reverse surface. Both the principal surface and the reverse surface of the graphite sheet 11 preferably have the particular structure described above. Making both the principal surface and the reverse surface have the particular structure allows both surfaces to be soft enough for the graphite sheet 11 to make even closer surface contact on both sides. This allows the contact thermal resistance to be further lowered at the surfaces, thus further improving the heat dissipation effects.

### <Method for Manufacturing Graphite Sheet>

Next, a method for manufacturing a graphite sheet according to this embodiment will be described.

A method for manufacturing a graphite sheet according to this embodiment includes: a first step of obtaining a graphite base member; and a second step of forming the graphite sheet by removing a surface portion of the graphite base member obtained in the first step.

### (First Step)

In this step, a graphite base member is obtained. First, a carbonized film is obtained by pyrolysis of a polyimide film with a thickness of about 100 μm, for example. The carbonized film is further fired at about 2600° C. to turn into graphite. In this manner, a graphite base member is obtained. The graphite base member produces a gas inside when subjected to the pyrolysis and turning into a graphite and expands in the thickness direction. Thus, the graphite base member has come to have a thickness of about 500 μm, for example, and therefore, is ready to be compressed as a whole when subjected to pressure. However, this surface layer has been crystallized significantly to make only the surface layer rather hard. That is why even if this graphite base member is sandwiched between the IGBT and the cooling member and fastened with screws, the graphite base member cannot make a sufficient contact, thus causing an increase in the contact thermal resistance.

### (Second Step)

In this step, a surface portion of the graphite base member obtained in the first step is removed to form a graphite sheet.

According to a method for removing the surface portion, a slicer such as NP1240C manufactured by Nippy Kikai Co., Ltd. may be used. Using a slicer to remove a surface portion of the graphite base member allows the graphite sheet 11 to be manufactured more easily. First, the graphite base member obtained by firing is fixed onto the slicer. Next, the graphite base member is sliced at a point about 50 μm from the surface. The graphite sheet 11 may be obtained by slicing the graphite base member at a point corresponding to a predetermined thickness. If the graphite base member is sufficiently thick, multiple graphite sheets 11 may be obtained, thus causing an increase in mass productivity as well.

As described above, the manufacturing method according to this embodiment achieves the following advantages by removing the surface portion in the second step:
(1) Through the surface of one graphite layer, which forms the outermost layer of the graphite sheet, at least a part of another graphite layer, other than the graphite layer forming the outermost layer, is exposed; and
(2) The apparent shear strength as measured by SAICAS method from a depth of 0.5 μm to a depth of 19 μm may fall within a particular range, thus allowing the graphite sheet 11 to make close contact with the IGBT and the cooling member and lowering the contact thermal resistance.

### (Recapitulation)

As can be seen from the foregoing description of embodiments, in a graphite sheet (11) according to a first aspect, a plurality of graphite layers are stacked one on top of another in a thickness direction. The plurality of graphite layers includes: a first graphite layer that forms an outermost layer of the graphite sheet (11); and a second graphite layer other than the first graphite layer. At least a part of the second graphite layer is exposed through a surface of the first graphite layer.

The first aspect allows the graphite sheet (11) to have a sufficiently soft surface, thus enabling lowering the contact thermal resistance at the surface and thereby achieving sufficient heat dissipation effects.

In a graphite sheet (11) according to a second aspect, which may be implemented in conjunction with the first aspect, the at least part of the second graphite layer forms a plurality of recesses, which has an average depth equal to or greater than 3 μm and equal to or less than 30 μm.

The second aspect improves the follow-up capability of the surface portion of the graphite sheet (11) so much as to decrease the thermal resistance. In addition, the thermal resistance does not increase because the air gap is not too wide. This enables further lowering the contact thermal resistance at the surface and further improving the heat dissipation effects. Furthermore, the plurality of recesses having such an average depth on the surface not only makes it even easier to form a composite structure with a resin member or any other suitable member by, for example, impregnation, but also ensures sufficient strength for the graphite sheet (11) as well.

In a graphite sheet (11) according to a third aspect, which may be implemented in conjunction with the second aspect, the plurality of recesses has a mean equivalent diameter equal to or greater than 30 μm and equal to or less than 100 μm.

The third aspect allows the graphite sheet (11) to make even closer surface contact, thus enabling further lowering the contact thermal resistance at the surface and further improving the heat dissipation effects.

In a graphite sheet (11) according to a fourth aspect, which may be implemented in conjunction with the second or third aspect, an average number of the plurality of recesses per unit area is equal to or greater than 5 per mm² and equal to or less than 30 per mm².

The fourth aspect allows the graphite sheet (11) to make even closer surface contact, thus enabling further lowering the contact thermal resistance at the surface and further improving the heat dissipation effects.

A graphite sheet (11) according to a fifth aspect has an apparent shear strength equal to or greater than 0.1 MPa and equal to or less than 0.5 MPa as measured by SAICAS method from a depth of 0.5 μm to a depth of 19 μm.

The fifth aspect allows the graphite sheet (11) to have a sufficiently soft surface, thus enabling lowering the contact thermal resistance at the surface and thereby achieving sufficient heat dissipation effects.

In a graphite sheet (11) according to a sixth aspect, which may be implemented in conjunction with the fifth aspect, F1 is less than F2, where F1 is the apparent shear strength of the graphite sheet (11) as measured by the SAICAS method from the depth of 0.5 μm to the depth of 19 μm and F2 is an apparent shear strength of the graphite sheet (11) as measured from a depth of 20 μm to “a” depth of a when the graphite sheet (11) has a thickness of “2a.”

The sixth aspect allows the graphite sheet (11) to have a more sufficiently soft surface, thus improving the follow-up capability of the recesses and thereby further lowering the contact thermal resistance.

In a graphite sheet (11) according to a seventh aspect, which may be implemented in conjunction with the sixth aspect, F1 and F2 satisfy F1/F2≥0.5.

The seventh aspect makes the surface portion of the graphite sheet (11) hardly scratchable, thus making it easier to handle the graphite sheet (11).

In a graphite sheet (11) according to an eighth aspect, which may be implemented in conjunction with any one of the first to seventh aspects, the graphite sheet (11) has a compressibility equal to or greater than 60% when subjected to a pressure of 600 kPa.

The eighth aspect enables lowering the contact thermal resistance sufficiently.

A method for manufacturing a graphite sheet (11) according to a ninth aspect includes: a first step of obtaining a graphite base member; and a second step of forming the graphite sheet (11) by removing a surface portion of the graphite base member obtained in the first step.

The ninth aspect allows the graphite sheet (11) to be obtained by a simple method.

In a method for manufacturing a graphite sheet (11) according to a tenth aspect, which may be implemented in conjunction with the ninth aspect, the graphite sheet (11) formed in the second step includes: a first graphite layer that forms an outermost layer of the graphite sheet (11); and a second graphite layer other than the first graphite layer. At least a part of the second graphite layer is exposed through a surface of the first graphite layer.

The tenth aspect enables providing, by a simple method, a graphite sheet (11) that has a surface soft enough to lower the contact thermal resistance at the surface and thereby achieve sufficient heat dissipation effects.

In a method for manufacturing a graphite sheet (11) according to an eleventh aspect, which may be implemented in conjunction with the ninth or tenth aspect, the graphite sheet (11) formed in the second step has an apparent shear strength equal to or greater than 0.1 MPa and equal to or less than 0.5 MPa as measured by SAICAS method from a depth of 0.5 μm to a depth of 19 μm.

The eleventh aspect enables providing, by a simple method, a graphite sheet (11) that has a surface soft enough to lower the contact thermal resistance at the surface and thereby achieve sufficient heat dissipation effects.

In a method for manufacturing a graphite sheet (11) according to a twelfth aspect, which may be implemented in conjunction with any one of the ninth to eleventh aspects, the second step includes removing the surface portion using a slicer.

The twelfth aspect makes it even easier to manufacture the graphite sheet (11) by using a slicer to remove a surface portion of the graphite base member.

### INDUSTRIAL APPLICABILITY

A graphite sheet according to the present disclosure enables lowering the contact thermal resistance at the surface and thereby achieving sufficient heat dissipation effects, and therefore, is effectively applicable on an industrial basis.

### REFERENCE SIGNS LIST

11 Graphite Sheet
12 Cutting Blade

1. A graphite sheet in which a plurality of graphite layers are stacked one on top of another in a thickness direction,
the plurality of graphite layers including: a first graphite layer that forms an outermost layer of the graphite sheet; and a second graphite layer other than the first graphite layer, at least a part of the second graphite layer being exposed through a surface of the first graphite layer.

2. The graphite sheet of claim 1, wherein
the at least part of the second graphite layer forms a plurality of recesses, and
the plurality of recesses has an average depth equal to or greater than 3 μm and equal to or less than 30 μm.

3. The graphite sheet of claim 2, wherein
the plurality of recesses has a mean equivalent diameter equal to or greater than 30 μm and equal to or less than 100 μm.

4. The graphite sheet of claim 2, wherein
an average number of the plurality of recesses per unit area is equal to or greater than 5 per mm² and equal to or less than 30 per mm².

5. A graphite sheet having an apparent shear strength equal to or greater than 0.1 MPa and equal to or less than 0.5 MPa as measured by SAICAS method from a depth of 0.5 μm to a depth of 19 μm.

6. The graphite sheet of claim 5, wherein
F1 is less than F2, where F1 is the apparent shear strength of the graphite sheet as measured by the SAICAS method from the depth of 0.5 μm to the depth of 19 μm and F2 is an apparent shear strength of the graphite sheet as measured from a depth of 20 μm to a depth of “a” when the graphite sheet has a thickness of “2a.”

7. The graphite sheet of claim 6, wherein
F1 and F2 satisfy F1/F2≥0.5.

8. The graphite sheet of claim 1, wherein
the graphite sheet has a compressibility equal to or greater than 60% when subjected to a pressure of 600 kPa.

9. A method for manufacturing a graphite sheet, the method comprising:
a first step of obtaining a graphite base member; and
a second step of forming the graphite sheet by removing a surface portion of the graphite base member obtained in the first step.

10. The method of claim 9, wherein
the graphite sheet formed in the second step includes: a first graphite layer that forms an outermost layer of the graphite sheet; and a second graphite layer other than the first graphite layer, at least a part of the second graphite layer being exposed through a surface of the first graphite layer.

11. The method of claim 9, wherein
the graphite sheet formed in the second step has an apparent shear strength equal to or greater than 0.1 MPa and equal to or less than 0.5 MPa as measured by SAICAS method from a depth of 0.5 μm to a depth of 19 μm.

12. The method of claim 9, wherein
the second step includes removing the surface portion using a slicer.

13. The graphite sheet of claim 5, wherein
the graphite sheet has a compressibility equal to or greater than 60% when subjected to a pressure of 600 kPa.
